(19) United States
(12) Patent Application Publication
(10) Pub. No.: US 2025/0364614 A1
(43) Pub. Date: Nov. 27, 2025

(54) METHOD OF MANUFACTURING SECONDARY BATTERY

(71) Applicant: TOYOTA JIDOSHA KABUSHIKI KAISHA, Toyota-shi (JP)

(72) Inventor: Shun TAKEOKA, Toyota-shi (JP)

(73) Assignee: TOYOTA JIDOSHA KABUSHIKI KAISHA, Toyota-shi (JP)

(21) Appl. No.: 19/220,369

(22) Filed: May 28, 2025

(30) Foreign Application Priority Data
Aug. 27, 2024 (JP) 2024-145883

(51) Int. Cl. H01M 10/44; G01R 31/388

(52) U.S. Cl. CPC H01M 10/446; G01R 31/388

(57) ABSTRACT

A method for manufacturing a secondary battery includes: preparing a secondary battery; and starting a self-discharge test of the secondary battery with a value of |dV/dt| of the secondary battery during self-discharge being greater than a reference value. The method may further include adjusting the remaining capacity of the secondary battery such that the value of |dV/dQ| of the secondary battery becomes greater than a threshold.

### CROSS-REFERENCE TO RELATED APPLICATION

This application claims priority to Japanese Patent Application No. 2024-145883 filed on Aug. 27, 2024. The disclosure of the above-identified application, including the specification, drawings, and claims, is incorporated by reference herein in its entirety.

### BACKGROUND

### 1. Technical Field

The present disclosure relates to methods for manufacturing a secondary battery.

### 2. Description of Related Art

Japanese Unexamined Patent Application Publication No. 2019-113450 (JP 2019-113450 A) discloses a technique of performing a self-discharge test of a secondary battery. In this technique, a circuit is formed by connecting a power supply to a secondary battery, and a self-discharge test of the secondary battery is performed by supplying a current from the power supply to the circuit.

### SUMMARY

However, J P 2019-113450 A does not sufficiently examine a temperature change during the self-discharge test. In the technique described in JP 2019-113450 A, the test accuracy may decrease if the ambient temperature changes during the self-discharge test.

The present disclosure was made to solve the above issue, and an object of the present disclosure is to appropriately perform a self-discharge test of a secondary battery.

One aspect of the present disclosure provides a method for manufacturing a secondary battery. The method includes:
preparing a secondary battery; and
starting a self-discharge test of the secondary battery with a value of |dV/dt| being greater than a reference value. The value of |dV/dt| is an absolute value of a derivative of a voltage V of the secondary battery during self-discharge with respect to time t.

With the present disclosure, it is possible to appropriately perform a self-discharge test of a secondary battery.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a flowchart illustrating a method of manufacturing a secondary battery according to an embodiment;

FIG. 2 is a cross-sectional view showing a stack constituting the secondary battery according to the embodiment;

FIG. 3 is a diagram for describing a self-discharge test of a cell after charging and charging of each cell in the method for manufacturing a secondary battery according to the embodiment;

FIG. 4 is a flowchart illustrating a method according to a comparative example;

FIG. 5 is a diagram showing data obtained by methods according to an example and a comparative example;

FIG. 6 is a diagram showing and when the ambient temperature changes in the methods according to the example and the comparative example; and

FIG. 7 is a diagram illustrating a modification of the flowchart shown in FIG. 1.

### DETAILED DESCRIPTION OF EMBODIMENTS

An embodiment of the present disclosure will be described in detail with reference to the drawings. The same or corresponding parts are denoted by the same signs throughout the drawings, and description thereof will not be repeated. In the drawings used below, among the X-axis, the Y-axis, and the Z-axis orthogonal to each other, the Z-axis represents the thickness direction of the battery. Hereinafter, “+” is indicated in the direction indicated by the arrows of the X-axis, the Y-axis, and the Z-axis, and “−” is indicated in the opposite direction.

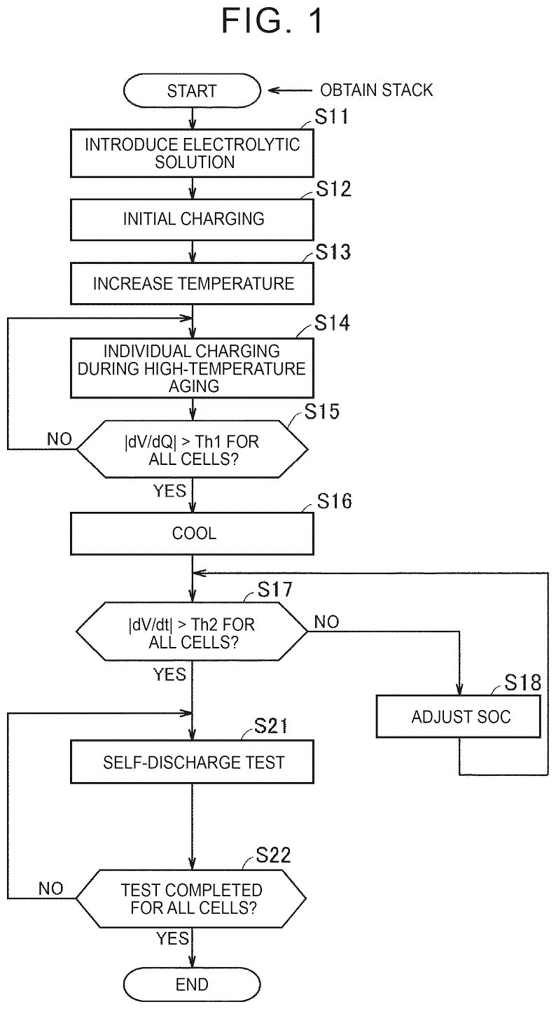

FIG. 1 is a flowchart illustrating a processing procedure of a method for manufacturing a secondary battery according to this embodiment. In the method for manufacturing a secondary battery according to this embodiment, a stack is first formed. Then, introduction of an electrolytic solution, charging, aging, self-discharge test, etc. are performed on the stack according to the process flow shown in FIG. 1. The process flow illustrated in FIG. 1 will be described in detail later.

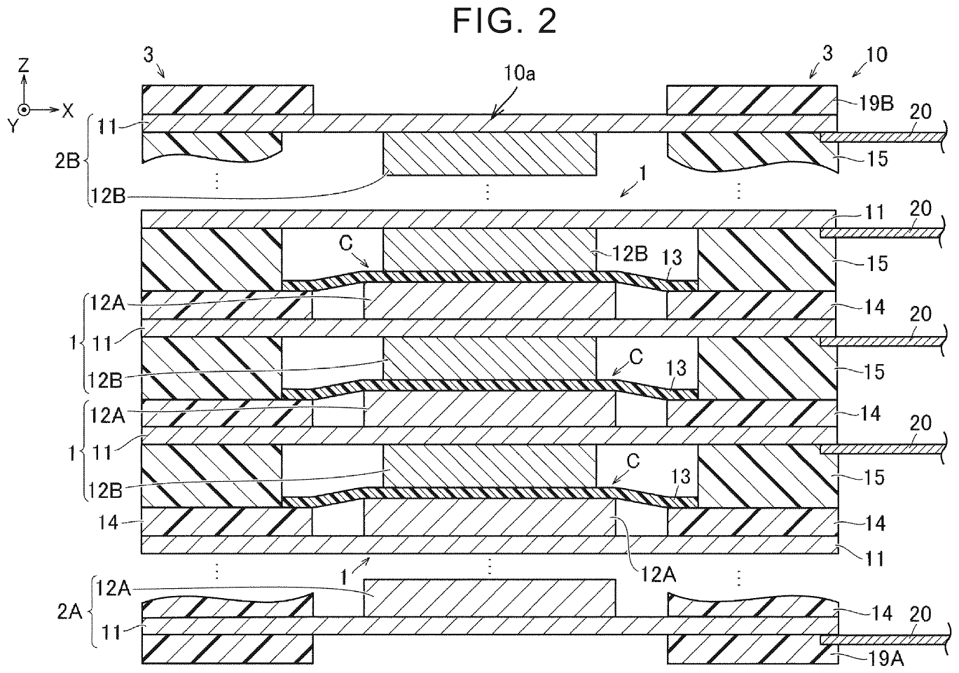

In the present embodiment, the stack 10 shown in FIG. 2 is prepared. FIG. 2 is a cross-sectional view showing a stack constituting the secondary battery according to the embodiment. Referring to FIG. 2, the stack 10 includes an energy storage portion 10a and a sealing portion 3 that seals the energy storage portion 10a. The Z-direction corresponds to the stacking direction. The energy storage portion 10a includes a plurality of cells C arranged in the Z-direction. Each of the plurality of cells C includes an anode active material layer 12A, a cathode active material layer 12B, and a separator 13. Each of the plurality of cells C is configured to store electricity. Each of the plurality of cells C functions as a secondary cell. Each of the plurality of cells C is an example of an “energy storage cell” according to the present disclosure. In the present embodiment, the energy storage portion 10a includes 10 or more cells C. However, the number of cells C can be set as desired. The number of cells C included in the energy storage portion 10a may be three or more and less than 50, or may be 50 or more. The sealing portion 3 is formed so as to surround the energy storage portion 10a.

The stack 10 includes a plurality of electrodes (one anode end electrode 2A, a plurality of bipolar electrodes 1, and one cathode end electrode 2B) stacked along the Z-direction. The separator 13 is disposed between the electrodes. The bipolar electrode 1 includes a current collector 11, an anode active material layer 12A provided on the surface on the +Z-side of the current collector 11, and a cathode active material layer 12B provided on the surface on the −Z-side of the current collector 11. The anode end electrode 2A has a configuration in which the cathode active material layer 12B is removed from the bipolar electrode 1. An insulating layer 19A covering the peripheral edge portion of the current collector 11 is formed on the surface on the −Z-side of the current collector 11 of the anode end electrode 2A. The cathode end electrode 2B has a configuration in which the anode active material layer 12A is removed from the bipolar electrode 1. An insulating layer 19B covering the peripheral edge portion of the current collector 11 is formed on the surface on the +Z-side of the current collector 11 of the cathode end electrode 2B.

In the present embodiment, a metal foil (for example, aluminum foil) is used as the current collector 11 of each electrode. A surface treatment (for example, plating treatment) may be applied to one or both surfaces of the metal foil. A voltage detection terminal 20 is connected to the current collector 11 of each electrode. In this embodiment, the voltage detection terminal 20 contains stainless steel (e.g., SUS304). Stainless steel is excellent in corrosion resistance, heat resistance, and workability. However, the material of the voltage detection terminal 20 can be changed as appropriate. Other metals (e.g., copper) may be employed instead of stainless steel.

The anode active material layer 12A contains an anode active material. The cathode active material layer 12B contains a cathode active material. In one example, the cathode active material is olivine lithium iron phosphate (LiFePO₄), and the anode active material is a carbon-based material. Other examples of the anode active material include silicon and tin.

In the stack 10, a cell C is formed between the plurality of stacked current collectors 11. Specifically, a cell C is formed between a current collector 11 (first current collector) and a current collector 11 (second current collector) adjacent to the first current collector. A cell C is also formed between the second current collector and a current collector 11 (third current collector) adjacent to the second current collector. The current collectors 11 and the cells C are thus alternately arranged in the stacking direction of the stack 10. The sealing portion 3 includes sealing layers 14, 15 disposed around each of the plurality of cells C included in the stack 10, and the insulating layers 19A, 19B described above. Any sealing material can be used as the material of the sealing portion 3.

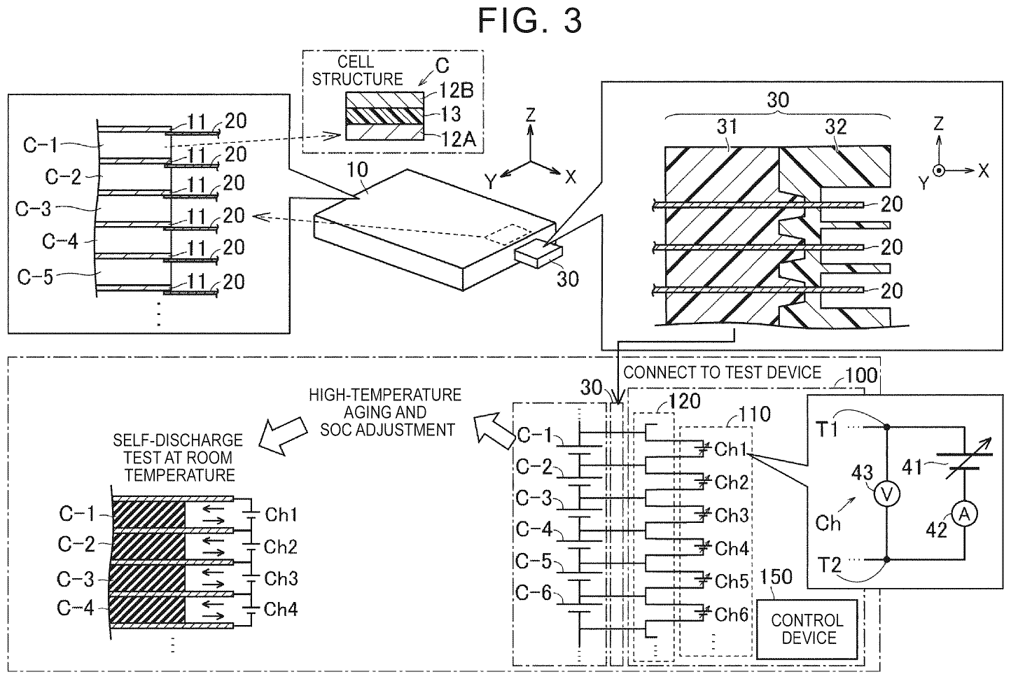

The stack 10 functions as a bipolar secondary battery. Each of the plurality of cells C included in the stack 10 (in particular, the energy storage portion 10a) functions as, for example, an olivine LFP cell (lithium-ion secondary cell including olivine lithium iron phosphate as a cathode active material). Hereinafter, the first, second, third, . . . cells C from the end on the cathode side (+Z-side) of the stack 10 are sometimes referred to as cell C-1, cell C-2, cell C-3, . . . , respectively (see FIG. 3 described later). In the stack 10, a plurality of cells is stacked in the Z-direction. Adjacent cells have a common electrode. Specifically, the current collector 11 and the voltage detection terminal 20 that are located between adjacent cells function as a common electrode. This common electrode functions as a common wire described later (see FIG. 3).

In a manufacturing system according to the present embodiment, the stack 10 (FIG. 2) with the voltage detection terminals 20 connected thereto is formed through various processes. Examples of the various processes include coating, pressing, seal welding, separator welding, cutting, terminal (voltage detection terminal) welding, end face welding, and electrolytic solution inlet port welding. Although not shown in FIG. 2, the voltage detection terminal 20 is further provided with a connector 30 (see FIG. 3), which will be described later. The stack 10 may be restrained by a restraining jig. The stack 10 may be sandwiched between a pair of end plates (restraining plates) and pressed.

The manufacturing system according to the present embodiment includes a system for preparing the stack 10 (system including devices corresponding to each process for forming the stack 10), and a test system for performing introduction of an electrolytic solution, charging, aging, and testing on the stack 10. However, manufacturing (including testing) of an energy storage device does not have to be automatically performed (that is, all processes related to the manufacturing do not have to be performed by the apparatus), and a person (worker) may perform part of the processes. The structure of the stack 10 is not limited to the structure shown in FIG. 2, and can be changed as appropriate.

Referring back to FIG. 1, once the stack 10 obtained as described above (e.g., the stack 10 in a restrained state) is passed to the test system, the test system automatically performs the process flow shown in FIG. 1 on the stack 10. Note that “S” in the flowchart means a step.

In S11, the test system introduces an electrolytic solution into the stack 10. The space surrounded by the sealing portion 3 in FIG. 2 is thus filled with the electrolytic solution. The separators 13 are impregnated with the electrolytic solution. The electrolytic solution is, for example, a non-aqueous electrolytic solution. However, the present disclosure is not limited thereto, and the electrolytic solution may be an aqueous electrolytic solution. Alternatively, a gel-like or solid-like electrolyte may be used instead of the electrolytic solution.

In S12, the test system then performs initial charging of the stack 10. The initial charging refers to charging the formed stack 10 for the first time. For example, the test system applies a voltage between the cathode terminal and the anode terminal of the stack 10 (for example, the current collectors 11 located at both ends in the Z-direction shown in FIG. 2). As a result, all the cells C connected in series are charged.

In S13, the test system then increases the temperature of the stack 10 to an aging temperature higher than room temperature. In the test system, for example, the stack 10 may be set in a thermostatic bath configured to perform temperature control, and the temperature of the stack 10 may be adjusted by the thermostatic bath. The aging temperature may be 50° C. or more and 85° C. or less. However, the aging temperature can be set as desired.

In S14, the test system then individually charges the cells while aging the stack 10 at the aging temperature (hereinafter referred to as “high-temperature aging”). Specifically, the test system performs CV (constant voltage) charging of each cell until |dV/dQ| becomes larger than a threshold (hereinafter, referred to as “Th1”). |dV/dQ| is an absolute value of the derivative of the cell voltage with respect to the remaining capacity. In the CV charging, a constant voltage applied to the cells may be equal to or higher than 3.7 V. Th1 is set such that |dV/dt| of each cell during self-discharge after completion of charging (more specifically, after cooling) of each cell becomes larger than a reference value (hereinafter, referred to as “Th2”). |dV/dt| is an absolute value of the derivative of the cell voltage during self-discharge with respect to time. For example, Th2 may be determined first, and Th1 may be determined based on Th2. The CV charge voltage, Th1, and Th2 are set according to the properties of the cell C.

Hereinafter, S14 and the subsequent steps will be described with further reference to FIG. 3. FIG. 3 illustrates charging of each cell and a self-discharge test of the cells after the charging. As shown in FIG. 3, the connector 30 is provided for the plurality of voltage detection terminals 20 (see FIG. 2) connected to the stack 10. The voltage detection terminal 20 is welded to, for example, the end on the +X-side of the current collector 11. Examples of a welding method include ultrasonic welding and laser welding. The connector 30 includes a resin portion 31 and a housing 32. For example, in a state in which the housing 32 for aligning the voltage detection terminals 20 is attached to the distal ends of the voltage detection terminals 20, the resin portion 31 connecting the end face on the +X-side of the stack 10 and the housing 32 is formed by injection molding. The connector 30 joined to the stack 10 is thus formed. The plurality of voltage detection terminals 20 is connectable to an external power supply (for example, a direct current power supply 41). Each of the voltage detection terminals 20 functions as a pin of the connector 30. The connector 30 is a male connector, and is configured to mate with a female connector (for example, a socket).

The test system according to this embodiment includes a test device 100. The test device 100 includes a power supply portion 110, a connection portion 120, and a control device 150. The control device 150 includes a processor and a storage device. In the present embodiment, the self-discharge test is conducted by a processor executing a program stored in the storage device. However, each process related to the self-discharge test may be performed only by hardware (electronic circuit) without using software.

The power supply portion 110 includes a plurality of channels for the self-discharge test (hereinafter, each channel will be referred to referred to as “Ch”). Each Ch includes a direct current power supply 41, an ammeter 42, a voltmeter 43, and terminals T1, T2. The output voltage of the direct current power supply 41 is variable. The direct current power supply 41 is controlled by the control device 150. The ammeter 42 is connected in series to the direct current power supply 41, and the voltmeter 43 is connected in parallel. The ammeter 42 detects a current flowing through a cell connected to Ch. The voltmeter 43 detects the voltage between the terminals T1, T2.

The connection portion 120 functions as a female connector that can be mated with the connector 30. In S14 in FIG. 1, the test device 100 connects the connector 30 to the connection portion 120. The test device 100 may include a robot to which a connector is connected. A corresponding terminal (for example, a female terminal) of the connection portion 120 is connected to each terminal (for example, a male terminal) of the connector 30. Each cell included in the stack 10 is thus connected to the power supply portion 110 of the test device 100. A test circuit is thus formed for each cell. The test circuit for the adjacent cells C (energy storage cells) includes a common wire portion. Each test circuit is a closed circuit including a cell C, a channel (Ch), and a common wire. In FIG. 3, Ch1, Ch2, Ch3, Ch4, Ch5, and Ch6 are Chs connected to cells C-1, C-2, C-3, C-4, C-5, and C-6, respectively.

In individual charging (S14) of each cell during high temperature aging, the power supply (direct current power supply 41) connected to the corresponding cell applies a voltage to the corresponding cell through the voltage detection terminal 20. Electric power is thus supplied from the corresponding power supply (direct current power supply 41) to each cell through the corresponding voltage detection terminal 20. Electric power (current) can be individually supplied to each cell by using the voltage detection terminals 20. Individually charging the cells facilitates accurate adjustment of the SOC (State Of Charge) of each cell. The SOC indicates the remaining capacity, and represents, for example, the ratio of the current remaining capacity to the full capacity, and is expressed in the range from 0% to 100%. For example, all cells may be charged simultaneously. However, the present disclosure is not limited thereto, and part of the cells may be charged preferentially. For example, individual charging one of the odd-numbered cells and the even-numbered cells may be performed first, and individual charging of the other of the odd-numbered cells and the even-numbered cells may then be performed. The odd-numbered cells are the odd-numbered cells C (cells C-1, C-3, . . . ) from the end on the cathode side of the stack 10. The even-numbered cells are the even-numbered cells C (cells C-2, C-4, . . . ) from the end on the cathode side of the stack 10.

Thereafter, in S15, the control device 150 determines whether |dV/dQ| of all the cells have become greater than Th1. While |dV/dQ| of any of the cells is equal to or less than Th1 (NO in S15), the CV charging (S14) is performed on those cells whose |dV/dQ| is equal to or less than Th1. The test device 100 stops charging those cells whose |dV/dQ| has become greater than Th1. The charging is thus stopped before the cells become fully charged, and overcharging is reduced. When |dV/dQ| of all cells have become greater than Th1 (YES in S15), the test system cools the stack 10 in S16. Specifically, the test system lowers the ambient temperature to room temperature. The high-temperature aging is thus completed. A device for keeping the stack 10 at a high temperature (e.g., a thermostatic bath) is removed from the stack 10.

Thereafter, in S17, the control device 150 determines whether |dV/dt| of each cell during self-discharge is greater than a reference value (Th2). The control device 150 may acquire the cell voltage based on the voltage detection result from the voltmeter 43 provided in each cell. In the present embodiment, the control device 150 determines Th2 such that the voltages of the cells do not increase during the test as long as the room temperature is within a predetermined temperature range during the self-discharge test. That is, when |dV/dt| of each cell during the self-discharge is greater than Th2 at the start of the self-discharge test (S21), the voltages of the cells will continue to drop as long as the room temperature does not vary beyond the predetermined temperature range during the test. Such Th2 may be determined in advance by experiments or simulations and stored in a storage device of the control device 150. The predetermined temperature range is set to, for example, around 25° C. The predetermined temperature range may be the range of 15° C. or more and 40° C. or less, or a range smaller than the range of 15° C. or more and 40° C. or less (any range within this range).

Cell information (e.g., a mathematical expression or a map) indicating the relationship between |dV/dQ| in the charge of the cell C and |dV/dt| during self-discharge after charge may be stored in advance in the storage device of the control device 150. Such cell information may be obtained in advance by experiments or simulations. The control device 150 determines |dV/dQ| corresponding to Th2, which is determined as described above, to be Th1 by using the cell information in the storage device. That is, when |dV/dQ| of each cell becomes greater than Th1 by the individual charge (S14) of each cell, the determination result in S17 is YES according to the calculation. However, the determination result in S17 may be NO due to the accuracy of calculation of the cell information and Th2 or individual differences between the cells C. Therefore, in the present embodiment, the process proceeds to S18 when the determination result in S17 is NO. In S18, the test device 100 adjusts the SOC of each cell. Specifically, the test device 100 performs additional charging such that |dV/dt| during self-discharge becomes greater than Th2 regarding the cells whose |dV/dt| during self-discharge did not become greater than Th2. Thereafter, the process returns to S17, and the determination result in S17 is YES.

When YES in S17, the process proceeds to S21. In S21, the test device 100 performs the self-discharge test of each cell at room temperature.

Specifically, the power supply (direct current power supply 41) connected to a cell to be tested applies a voltage to the cell through the voltage detection terminal 20. In the present embodiment, the direct current power supply 41 applies to the cell a power supply voltage that is equal in magnitude and opposite in direction to the cell voltage at the start of the test. The control device 150 determines whether the current has converged for the cell to be tested, and estimates the converged current value as the self-discharge current for the cell for which the current has been determined to have converged. The control device 150 may determine that the current has converged when the amount of change in current per unit time becomes equal to or less than a predetermined value. However, the present disclosure is not limited to this, and any method may be used to determine whether a current has converged. The control device 150 may determine whether the cell is satisfactory or not based on the estimated self-discharge current of the cell. For example, the control device 150 determines that a cell whose self-discharge current is equal to or higher than a predetermined reference value (hereinafter, referred to as “Is”) is a short-circuit cell (defective product).

Subsequently, in S22, the test device 100 determines whether the self-discharge test has been completed for all the cells in the stack 10. While the self-discharge test has not been completed for all of the cells, the determination result in S22 is NO, and S21, S22 are repeated. Then, when the self-discharge test has been completed for all the cells (YES in S22), the process shown in FIG. 1 ends.

The test device 100 may determine that the stack 10 is a defective product when the stack 10 includes at least one short-circuited cell. When it is determined that the self-discharge current is equal to or greater than Is value for at least one cell included in the stack 10, the process flow of FIG. 1 for the stack 10 may end. When the process flow shown in FIG. 1 ends, the test system may start the process flow shown in FIG. 1 for the next test target (secondary battery). As described above, by ending the test at the time when the determination result of the quality of a certain secondary battery is known and shifting to the test of the next secondary battery, it is possible to improve the efficiency of the test.

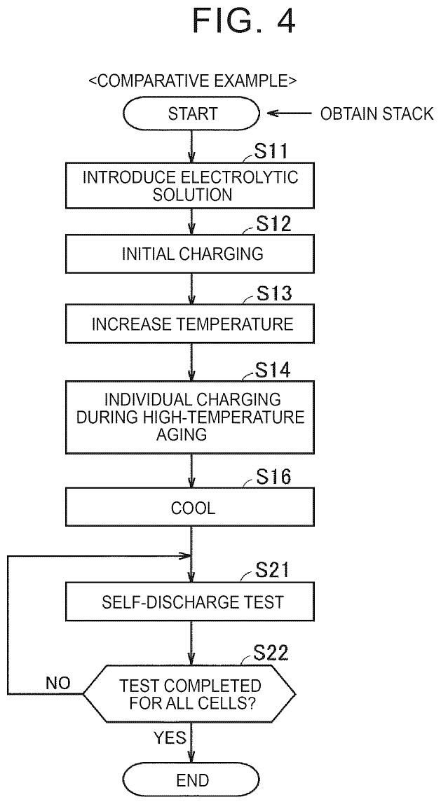

As described above, by measuring the converged value of a very small leakage current (for example, a current of several microamperes to several hundreds of microamperes) of the secondary battery, it is possible to measure the self-discharge current of the secondary battery with high accuracy in a short time. However, a very small leakage current tends to fluctuate due to a temperature change. Hereinafter, the functions and effects of the method for manufacturing a secondary battery according to the present embodiment (the method according to the example) will be described in comparison with the method according to the comparative example. The method according to the example uses the above process flow shown in FIG. 1. On the other hand, FIG. 4 is a flowchart showing a method according to a comparative example. As shown in FIG. 4, the method according to the comparative embodiment uses a process flow in which S15, S17, S18 in the process flow shown in FIG. 1 are omitted.

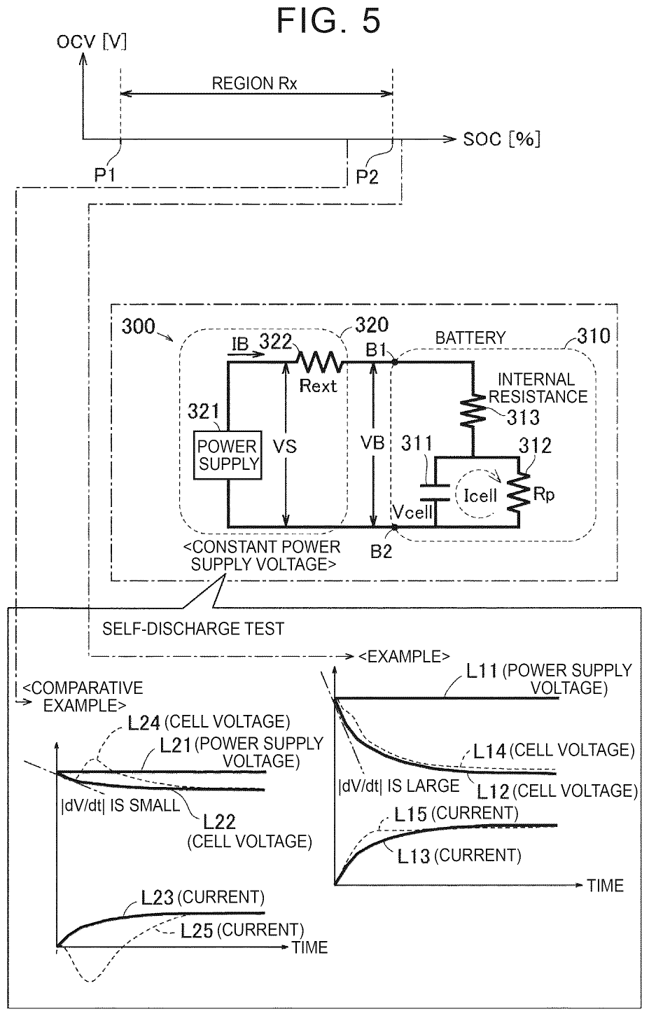

FIG. 5 is a diagram illustrating data obtained by the method according to the example and data obtained by the method according to the comparative example. Each of the lines L11 to L15 is related to the method according to the example. Each of the lines L21 to L25 is related to the method according to the comparative embodiment.

Hereinafter, in a graph showing the charge properties of the cell C (olivine LFP cell), the SOC region above the lower limit of the region and below the upper limit of the region is referred to as “region Rx”. The graph indicating the charge property of the cell C is, for example, a graph in which the vertical axis represents OCV (open-circuit voltage) of the cell C and the horizontal axis represents SOC of the cell C. The lower limit of the region is hereinafter referred to as “P1”. The upper limit of the region is hereinafter referred to as “P2”. In the region Rx, |dV/dQ| is equal to or less than a predetermined value, and the voltage of the cell C hardly changes even if the remaining capacity of the cell C changes. On the other hand, in each of the region in which the SOC is lower than P1 and the region in which the SOC is higher than P2, the slope (|dV/dQ|) of the graph becomes larger than the region Rx. In the region in which the SOC is lower than P1, the smaller the remaining capacity, the greater |dV/dQ| becomes. In the region in which the SOC is higher than P2, the larger the remaining capacity, the greater |dV/dQ|. |dV/dQ| is an absolute value of the derivative of the voltage (e.g., OCV) of the cell C with respect to the remaining capacity (e.g., SOC). |dV/dQ| is the ratio of the amount of change in voltage of the cell C to the amount of change in remaining capacity of the cell C. |dV/dQ| in the region Rx is small.

The greater |dV/dQ| of the cell C, the greater |dV/dt| of the cell C during self-discharge. Therefore, in the region in which the SOC of the cell C is higher than P2, the larger the remaining capacity of the cell C, the greater |dV/dQ| of the cell C during self-discharge. |dV/dt| is an absolute value of the derivative of the cell voltage with respect to time.

In the method according to the comparative example, individual charge of the cells is performed without considering |dV/dt| of each cell during the self-discharge. Specifically, in the method according to the comparative example, the individual charge was terminated before the SOC of each cell reaches P2 so that the cells did not become overcharged. Then, the self-discharge test was started with the SOC of each cell being in the region Rx.

On the other hand, in the method according to the example, individual charge of each cell is performed such that the SOC of each cell becomes higher than P2 and |dV/dQ| of each cell becomes greater than Th1. However, the individual charge of each cell was stopped before a corresponding cell becomes fully charged. This reduces overcharging of the cells. In the method according to the example, after individual charge of each cell was performed, the self-discharge test was started with |dV/dt| of each cell being greater than Th2.

In any of the methods of the example and the comparative example, a test circuit (closed circuit including a power supply) is formed for each cell (see FIG. 3). The test circuit of each cell has the same configuration as the circuit 300 shown in FIG. 5. The circuit 300 includes a battery circuit 310 and a power supply circuit 320. The battery circuit 310 corresponds to an equivalent circuit model of one cell. An electromotive element 311, a short-circuit resistor 312 connected in parallel with the electromotive element 311, and an internal resistor 313 connected in series with the electromotive element 311 are present between the terminals B1, B2 of the battery circuit 310. The electromotive force (hereinafter referred to as “Vcell”) of the electromotive element 311 decreases due to self-discharge of the cell. The self-discharge current of the cell (hereinafter referred to as “Icell”) flows through the short-circuit resistor 312. The smaller the resistance of the short-circuit resistor 312 (hereinafter referred to as “Rp”) is, the larger Icell becomes. The voltage between the terminals of the battery circuit 310 (hereinafter, referred to as “VB”) corresponds to a potential difference (cell voltage) between the cathode and the anode of the cell. The power supply circuit 320 includes a direct current power supply 321 and a circuit resistor 322. The direct current power supply 321 outputs a voltage (hereinafter, referred to as “VS”). The resistance value (hereinafter referred to as “Rext”) of the circuit resistor 322 is, for example, the sum of the parasitic resistances present in the entire circuit. The parasitic resistance includes a contact resistance in addition to a wiring resistance (electric resistance of each conductor constituting the circuit). Hereinafter, the current flowing through the circuit 300 by VS will be referred to as “IB”.

In the self-discharge tests of both the example and the comparative example, during the test, the direct current power supply 41 (FIG. 3) of the corresponding Ch continued to apply to the cell a power supply voltage that is equal in magnitude and opposite in direction to the cell voltage at the start of the test. That is, during the test, the power supply voltage was kept constant (see lines L11, L21). The direct current power supply 41 shown in FIG. 3 functions as the direct current power supply 321 in the circuit 300. When the output voltage (VS) of the direct current power supply 321 is constant, the expression “IB=(VS−VB)/Rext” is established.

The self-discharge test is started by the application of the power supply voltage. At the start of the test, the cell voltage (VB) is equal to the power supply voltage (VS). Therefore, the circuit current (IB) becomes zero. Thereafter, when VB decreases due to self-discharge of the cell, IB increases. When IB increases and becomes equal to the self-discharge current (Icell), the decrease in VB stops and the cell voltage becomes constant. The increase in IB also stops and IB converges. Then, the converged value of IB indicates the self-discharge current. Based on these principles, a self-discharge current can be acquired from the current value (IB).

However, in the methods according to both the example and the comparative example, the self-discharge test was performed in a room temperature environment. The stack 10 connected to the power supply portion 110 of the test device 100 was placed in a room temperature environment without being subjected to temperature adjustment by an external device (for example, a thermostatic bath). In this way, the cost for temperature adjustment can be reduced. However, the room temperature may vary during the test. When the room temperature (ambient temperature) fluctuates, IB may behave differently from the above principles.

For lines L11 to L13 and lines L21 to L23, the abscissa represents the elapsed time since the start of the test. In the method according to the comparative example, |dV/dt| of each cell at the start of the test is about 0.3 mV/day (amount of change in cell voltage per day). When the ambient temperature did not change, VB (line L22) and IB (line L23) behaved according to the above principles. When the ambient temperature does not change, |dV/dt| is considered to hardly change from the value at the start of the test. On the other hand, the behaviors of VB (line L24) and IB (line L25) greatly changed when the ambient temperature changed. As shown by the line L25, IB behaved differently than the above principles. It is presumed that the variation in IB is caused by the variation in VB due to the thermal change. The variation in the current value leads to a decrease in the accuracy of the self-discharge test. In the method according to the comparative example, it is considered that IB is susceptible to thermal fluctuations because |dV/dt| at the start of the test is small.

On the other hand, in the method according to the example, |dV/dt| of each cell at the start of the test was about 9 mV/day (amount of change in cell voltage per day). It is considered that, if |dV/dt| when there is no temperature change during self-discharge is sufficiently large, a change in VB due to the temperature change is relatively small, and the change in VB due to the temperature change is negligible. In the method according to the example, both VB (line L12) and IB (line L13) when the ambient temperature does not change and VB (line L14) and IB (line L15) when the ambient temperature changes also behave according to the above principles. According to the method according to the example, the self-discharge current of each cell can be easily measured with high accuracy.

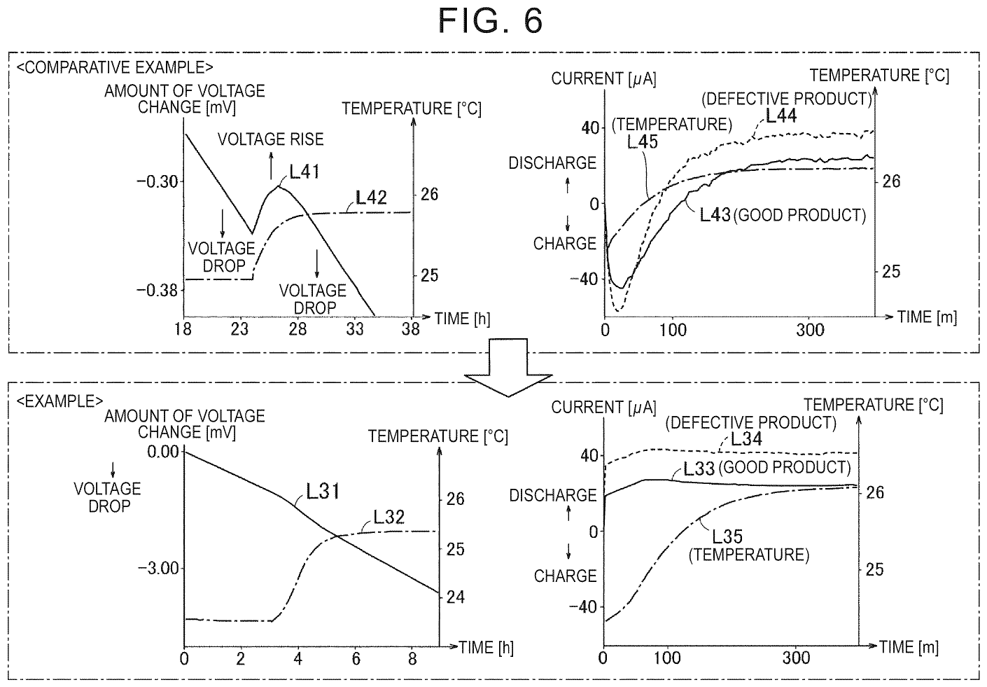

FIG. 6 is a diagram showing data when the ambient temperature changes in the methods according to the example and the comparative example.

For lines L31, L32 and L41, L42, the abscissa represents the elapsed time since the examination began. The line L41 indicates how the amount of change in VB changed when the room temperature (ambient temperature) changed as shown by the line L42 in the method according to the comparative example. In the method according to the comparative example, the change in VB (line L42) turned from falling to rising during the examination due to the change in the ambient temperature. On the other hand, the line L31 indicates how the amount of change in VB changed when the room temperature (ambient temperature) changed as shown by the line L32 in the method according to the example. In the method according to the example, VB continued to drop even if the ambient temperature changes during the test (line L32).

With respect to L35 from the line L33 and L45 from the line L43, the horizontal axis indicates the elapsed time from the timing at which the change of the room temperature (ambient temperature) starts. The lines L43, L44 respectively show how the IBs of good cells and short-circuited cells (defective products) changed when the room temperature (ambient temperature) changed as shown by the line L45 in the method according to the comparative example. In the method according to the comparative example, IB (line L44) of the short-circuited cells became smaller than IB (line L43) of the good cells, although temporarily, when the ambient temperature fluctuated. This behavior of IB leads to a decrease in the accuracy of the self-discharge test. On the other hand, the lines L33, L34 respectively show how the IBs of good cells and short-circuited cells (defective products) changed when the room temperature (ambient temperature) changed as shown by the line L35 in the method according to the example. In the method according to the example, IB (line L34) of the short-circuited cells is not smaller than IB (line L33) of the good cells even when the ambient temperature fluctuates. According to such a method, the self-discharge current of each cell can be measured with high accuracy.

As described above, the method of manufacturing the secondary battery according to the present embodiment includes the steps shown in FIG. 1. Specifically, the manufacturing system prepares a cell C (secondary battery) (see FIGS. 2 and 3). The manufacturing system adjusts the remaining capacity of the cell C such that |dV/dQ| of the cell C becomes greater than the threshold (Th1) (S12, S14, S15). After adjusting the remaining capacity of the cell C, the self-discharge test of the cell C is started with |dV/dt| of the cell C during self-discharge being greater than the reference value (Th2) (S17, S18, S21). According to such a method, the self-discharge current of each cell can be measured with high accuracy (see FIGS. 5 and 6). Such a method is considered to eliminate the need to cover the secondary battery with the heat insulating material and the need to wait until the temperature of the secondary battery is stabilized. Therefore, a high-quality secondary battery can be easily manufactured with high efficiency.

The stack 10 determined to be a good product by the above test can function as a bipolar secondary battery alone. However, a bipolar secondary battery may be manufactured by combining a plurality of modules using the stack 10 as one module. The manufactured secondary battery may be mounted on a moving body. Exemplary mobile objects include automobiles (such as a battery electric vehicle and a hybrid electric vehicle), vehicles other than automobiles, and mobile machines (such as agricultural machines and building machines). However, the use of the battery is arbitrary, and a stationary battery may be manufactured by the above method.

The process flow illustrated in FIG. 1 can be changed as appropriate. For example, the order of steps may be changed or the content of any of the steps may be changed according to the purpose.

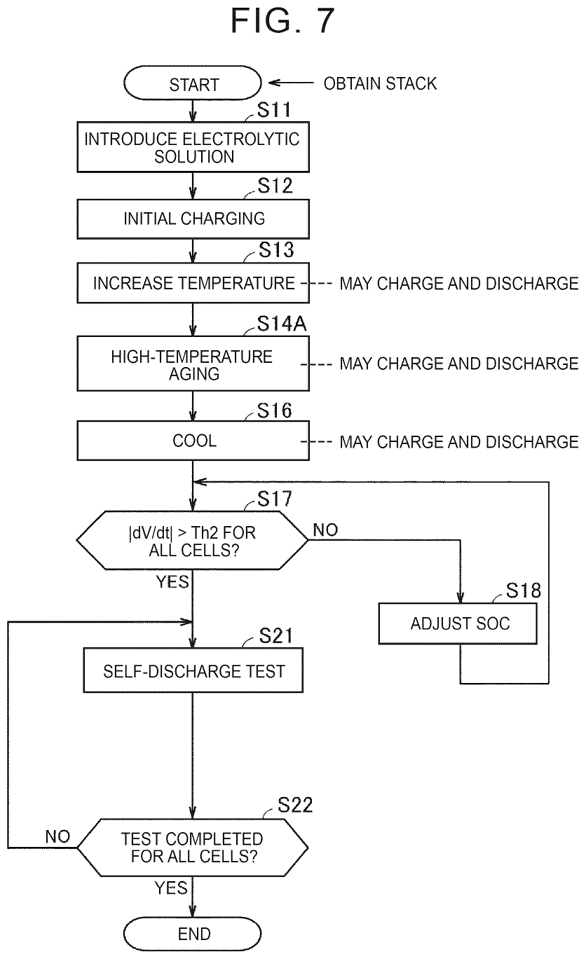

The test system may execute the process flow shown in FIG. 7 instead of the process flow shown in FIG. 1. FIG. 7 is a diagram illustrating a modification of the flowchart illustrated in FIG. 1. In the process shown in FIG. 7, S15 shown in FIG. 1 is omitted, and S14A is used instead of S14 (FIG. 1). In S14A, as in S14, high-temperature aging of the stack 10 is performed. However, the individual charge may not be performed in S14A. The process of adjusting the remaining capacity of each cell (e.g., charging or discharging each cell) may be performed in at least one of S13, S14A, and S16. In the process shown in FIG. 7, when |dV/dt| of each cell during the self-discharge is not larger than the reference value (Th2) (NO in S17), a process of adjusting the remaining capacity of each cell (for example, charge or discharge of each cell) is performed in S18. In a form in which the remaining capacity can be reliably adjusted by adjusting the remaining capacity in advance (at least one of S12, S13, S14A, and S16), the determination process (S17) may be omitted. The process of adjusting the remaining capacity of each cell may be performed after cooling of each cell (before the self-discharge test).

In the above embodiment, the remaining capacity of each cell is adjusted such that |dV/dQ| of each cell becomes greater than Th1 by charging. However, the present disclosure is not limited thereto, and the remaining capacity of each cell may be adjusted such that |dV/dQ| of each cell becomes greater than Th1 by discharging. For example, the self-discharge test may be performed in a region where SOC is higher than 0% and lower than P1 for the cell C having the region Rx described above.

In the above embodiment, the self-discharge current of the secondary battery is estimated based on the converged value of the current of the secondary battery during the self-discharge. However, the method of measuring the self-discharge current in during self-discharge test is not limited to such a method. For example, the amount of voltage drop caused by self-discharge of the secondary battery may be measured, and the self-discharge current of the secondary battery may be estimated based on the measured amount of voltage drop. The type of the secondary battery to be tested is not limited to LFP battery, and may be any type. The secondary battery to be tested may be a monopolar secondary battery.

The embodiment disclosed this time should be considered to be illustrative in all respects and not restrictive. It is intended that the scope of the disclosure be defined by the appended claims rather than the description of the embodiments described above, and that all changes within the meaning and range of equivalency of the claims be embraced therein.

What is claimed is:

1. A method for manufacturing a secondary battery, the method comprising:
preparing a secondary battery; and
starting a self-discharge test of the secondary battery with a value of |dV/dt| being greater than a reference value, the value of |dV/dt| being an absolute value of a derivative of a voltage V of the secondary battery during self-discharge with respect to time t.

2. The method according to claim 1, further comprising, before the starting the self-discharge test, adjusting a remaining capacity of the secondary battery such that a value of |dV/dQ| becomes greater than a threshold, the value of |dV/dQ| being an absolute value of a derivative of the voltage V of the secondary battery with respect to a remaining capacity Q of the secondary battery.

3. The method according to claim 2, wherein, in the adjusting the remaining capacity of the secondary battery, charging of the secondary battery is performed such that the value of |dV/dQ| of the secondary battery becomes greater than the threshold, and the charging is stopped before the secondary battery is fully charged.

4. The method according to claim 2, wherein:
the self-discharge test of the secondary battery is performed in a room temperature environment;
the reference value is determined such that the voltage of the secondary battery does not increase during the self-discharge test of the secondary battery as long as a room temperature is within a predetermined temperature range during the self-discharge test; and
the threshold is determined based on the reference value.

5. The method according to claim 2, wherein:
the secondary battery is a bipolar secondary battery including a plurality of energy storage cells;
each of the energy storage cells includes a voltage detection terminal that is connectable to an external power supply;
the method further includes connecting a power supply to each of the voltage detection terminals of the energy storage cells;
in the adjusting the remaining capacity of the secondary battery, each of the power supplies that is connected to a corresponding one of the energy storage cells charges the corresponding one of the energy storage cells by applying a voltage to the corresponding one of the energy storage cells through a corresponding one of the voltage detection terminals; and
the self-discharge test of the secondary battery includes
applying a power supply voltage from each of the power supplies that is connected to a corresponding one of the energy storage cells to the corresponding one of the energy storage cells through a corresponding one of the voltage detection terminals, the power supply voltage being a voltage that is equal in magnitude and opposite in direction to a voltage of the corresponding one of the energy storage cells at a start of the self-discharge test,
determining, for each of the energy storage cells, whether a current has converged, and
estimating, for the energy storage cell for which the current is determined to have converged, a converged value of the current as a self-discharge current.
